(19) United States
(12) Patent Application Publication
(10) Pub. No.: US 2024/0258277 A1
(43) Pub. Date: Aug. 1, 2024

(54) SEMICONDUCTOR PACKAGES AND METHOD FOR FABRICATING THE SAME

(71) Applicant: SAMSUNG ELECTRONICS CO., LTD., SUWON-SI (KR)

(72) Inventors: YI EOK KWON, SUWON-SI (KR); JINGU KIM, SUWON-SI (KR); SANGKYU LEE, SUWON-SI (KR)

(21) Appl. No.: 18/457,504

(22) Filed: Aug. 29, 2023

(30) Foreign Application Priority Data
Jan. 26, 2023 (KR) 10-2023-0010395

(51) Int. Cl. H01L 25/065; H01L 21/56; H01L 23/00; H01L 23/538; H01L 25/00

(52) U.S. Cl. CPC H01L 25/0657; H01L 21/568; H01L 23/5389; H01L 24/05; H01L 24/08; H01L 24/16; H01L 24/17; H01L 24/32; H01L 24/73; H01L 24/80; H01L 24/81; H01L 24/83; H01L 24/92; H01L 25/50; H01L 24/06; H01L 25/18; H01L 2224/0557; H01L 2224/05647; H01L 2224/06181; H01L 2224/08145; H01L 2224/16145; H01L 2224/16227; H01L 2224/17181; H01L 2224/32145; H01L 2224/73204; H01L 2224/73253; H01L 2224/80006; H01L 2224/80357; H01L 2224/80379; H01L 2224/80896; H01L 2224/81005; H01L 2224/83005; H01L 2224/9211; H01L 2224/92125; H01L 2225/06513; H01L 2225/06517; H01L 2225/06541; H01L 2924/0544; H10B 80/00

(57) ABSTRACT

A semiconductor package includes: a front side redistribution layer; a three-dimensional integrated circuit (3D IC) structure on the front side redistribution layer, the 3D IC structure including a first semiconductor chip die having through-silicon vias (TSVs) and a second semiconductor chip die disposed on the first semiconductor chip die, and the second semiconductor chip die being electrically coupled with the front side redistribution layer by the through-silicon vias (TSVs); a plurality of connection members between the first semiconductor chip die and the second semiconductor chip die; an insulating member disposed between the first semiconductor chip die and the second semiconductor chip die to surround the plurality of connection members; a molding material disposed on the front side redistribution layer to encapsulate the first semiconductor chip die, the second semiconductor chip die, and the insulating member; and a back side redistribution layer disposed on the molding material.

### CROSS-REFERENCE TO RELATED APPLICATION

This U.S. patent application claims priority under 35 U.S.C § 119 to Korean Patent Application No. 10-2023-0010395 filed in the Korean Intellectual Property Office on Jan. 26, 2023, the disclosure of which is incorporated by reference herein.

### (a) TECHNICAL FIELD

The present disclosure relates to semiconductor packages and a method for fabricating the same.

### (b) DISCUSSION OF RELATED ART

The semiconductor industry needs to increase integration density so that more passive or active devices can be integrated into a given area of a semiconductor device. Widths of circuit lines within the semiconductor device may be reduced to increase the integration density. However, reducing these circuit line widths faces limitations. For this reason, semiconductor packaging technologies have been used to supplement these limitations. Package-on-package (POP) is one of the semiconductor packaging technologies used for stacking an upper semiconductor package on top of a lower semiconductor package.

An existing package-on-package (POP) technology may form a lower semiconductor package by mounting a semiconductor chip on a front side redistribution layer (FRDL) and forming a back side redistribution layer (BRDL) on the lower semiconductor package, and connecting an upper semiconductor package to the upper part of the lower semiconductor package through the back side redistribution layer (BRDL).

For example, the semiconductor chip may be a system-on-chip (SOC), which is one semiconductor chip having individual semiconductors, such as microprocessors, memory semiconductors, digital signal processing chips, and wireless modems, integrated therein.

However, when any of the individual semiconductors in the system-on-chip (SOC) is defective, the entire SOC is needs to be discarded. Therefore, it is required to develop a new semiconductor packaging technology capable of solving the problems of the existing package-on-package (POP) technology.

### SUMMARY

Embodiments of the present invention has been made in an effort to provide a semiconductor package and a method for fabricating the semiconductor package capable of implementing a system-on-chip (SOC) as a three-dimensional integrated circuit (3D IC) structure by distinguishing individual semiconductors to be included in a system-on-chip (SOC) included in the package-on-package (POP) technology under a predetermined criterion, and stacking each of the individual semiconductors on a front side redistribution layer (FRDL) in a package-on-package (POP) fabricating process.

An embodiment of the present invention provides a semiconductor package including: a front side redistribution layer; a three-dimensional integrated circuit (3D IC) structure disposed on the front side redistribution layer; a plurality of connection members; an insulating member; a molding material; and a back side redistribution layer. The 3D IC structure includes a first semiconductor chip die having through-silicon vias (TSVs) and a second semiconductor chip die disposed on the first semiconductor chip die. The second semiconductor chip die is electrically coupled to the front side redistribution layer by the through-silicon vias (TSVs). The plurality of connection members are disposed between the first semiconductor chip die and the second semiconductor chip die. The insulating member is disposed between the first semiconductor chip die and the second semiconductor chip die to surround the plurality of connection members. The molding material is disposed on the front side redistribution layer so as to encapsulate the first semiconductor chip die, the second semiconductor chip die, and the insulating member. The back side redistribution layer is disposed on the molding material.

Each connection member of the plurality of connection members may include micro bumps.

The insulating member may include a molded underfill (MUF) material.

The insulating member may include a non-conductive film (NCF).

Each connection member of the plurality of connection members may include a first bonding pad bonded to the first semiconductor chip die, and a second bonding pad bonded to the second semiconductor chip die.

The first bonding pad may be directly bonded to the second bonding pad.

The first bonding pad and the second bonding pad may include copper (Cu).

The insulating member may include a first insulating layer bonded to the first semiconductor chip die, and a second insulating layer bonded to the second semiconductor chip die.

The first insulating layer may be directly bonded to the second insulating layer.

The first insulating layer and the second insulating layer may include silicon oxide.

Another embodiment of the present invention provides a semiconductor package including: a front side redistribution layer; a three-dimensional integrated circuit (3D IC) structure disposed on the front side redistribution layer; a plurality of first connection members; a plurality of second connection members; an insulating member; a plurality of conductive posts; a molding material; a back side redistribution layer; and a third semiconductor chip die. The 3D IC structure includes a first semiconductor chip die having through-silicon vias (TSVs) and a second semiconductor chip die disposed on the first semiconductor chip die. The second semiconductor chip die is electrically coupled to the front side redistribution layer by the through-silicon vias (TSVs). The plurality of first connection members are disposed between the first semiconductor chip die and the second semiconductor chip die to electrically couple the first semiconductor chip die to the second semiconductor chip die. The plurality of second connection members are disposed between the first semiconductor chip die and the front side redistribution layer to electrically couple the first semiconductor chip die to the front side redistribution layer. The insulating member is disposed between the first semiconductor chip die and the second semiconductor chip die to surround the plurality of first connection members. The plurality of conductive posts are bonded to the front side redistribution layer and disposed side by side next to the 3D IC structure on the front side redistribution layer. The molding material is disposed on the front side redistribution layer to encapsulate the first semiconductor chip die, the second semiconductor chip die, the insulating member, the plurality of second connection members, and the plurality of conductive posts. The back side redistribution layer is disposed on the molding material and the plurality of conductive posts and bonded to the plurality of conductive posts. The third semiconductor chip die is disposed on the back side redistribution layer.

The first semiconductor chip die may include a central processing unit (CPU) or a graphic processing unit (GPU).

The second semiconductor chip die may include a communication chip or sensor.

The third semiconductor chip die may include a memory semiconductor.

The 3D IC structure may include a system-on-chip (SOC).

The molding material may include an epoxy molding compound (EMC).

Another embodiment of the present invention provides a method for fabricating a semiconductor package including: forming a front side redistribution layer on a carrier; a step of forming a 3D IC structure on the front side redistribution layer, comprising: mounting a first semiconductor chip die to the front side redistribution layer; a step of bonding a second semiconductor chip die to the first semiconductor chip die using a plurality of connection members, the plurality of connection members being surrounded by an insulating member; encapsulating the first semiconductor chip die, the second semiconductor chip die, and the insulating member on the front side redistribution layer within a molding material; and forming a back side redistribution layer on the molding material.

The bonding of the second semiconductor chip die to the first semiconductor chip die using the plurality of connection members may be performed by hybrid bonding.

The bonding of the second semiconductor chip die to the first semiconductor chip die using the plurality of connection members may include attaching a non-conductive film (NCF) to the first semiconductor chip die, and attaching the second semiconductor chip die to the non-conductive film (NCF).

The method for fabricating the semiconductor package may further include filling a molded underfill (MUF) material between the first semiconductor chip die and the second semiconductor chip die, after the bonding of the second semiconductor chip die to the first semiconductor chip die using the plurality of connection members.

According to an embodiment, to prevent the yield of system-on-chips (SOCs) from decreasing due to defects of semiconductors fabricated using old processes at low manufacturing costs, such as wireless modems, system-on-chips (SOCs) in the package-on-package (POP) technology can be implemented as 3D IC structures.

According to an embodiment, the fabricating process of sequentially stacking system-on-chips (SOCs) as 3D IC structures is included in the package-on-package (POP) fabricating process. Therefore, it is not necessarily required to perform a process of separately fabricating 3D IC structures, and it is possible to reduce use of an epoxy molding compound (EMC) for encapsulating 3D IC structures when separately fabricating 3D IC structures.

### BRIEF DESCRIPTION OF THE DRAWINGS

FIG. 1 is a cross-sectional view illustrating a semiconductor package of an embodiment including a 3D IC structure made by sequentially stacking a first semiconductor chip die and a second semiconductor chip die using connection members in the process of fabricating the semiconductor package.

FIG. 2 is a cross-sectional view illustrating a semiconductor package of an embodiment including a 3D IC structure made by sequentially stacking a first semiconductor chip die and a second semiconductor chip die by hybrid bonding in the process of fabricating the semiconductor package.

FIG. 3 is a cross-sectional view illustrating a step of providing a first carrier in a method for fabricating a semiconductor package.

FIG. 4 is a cross-sectional view illustrating a step of forming a front side redistribution layer on a release layer formed on the first carrier in the method for fabricating the semiconductor package.

FIG. 5 is a cross-sectional view illustrating a step of forming conductive posts on the front side redistribution layer in the method for fabricating the semiconductor package.

FIG. 6 is a cross-sectional view illustrating a step of bonding a first semiconductor chip die on the front side redistribution layer in the method for fabricating the semiconductor package.

FIG. 7A is a cross-sectional view illustrating a step of bonding a second semiconductor chip die on the first semiconductor chip die using connection members, following the step of FIG. 6 in the method for fabricating the semiconductor package.

FIG. 7B is a cross-sectional view illustrating a step of bonding a second semiconductor chip die to the first semiconductor chip die by hybrid bonding, following the step of FIG. 6, in the method for fabricating the semiconductor package.

FIG. 8 is a cross-sectional view illustrating a step of encapsulating the 3D IC structure and the conductive posts with a molding material, in the method for fabricating the semiconductor package.

FIG. 9 is a cross-sectional view illustrating a step of planarizing the upper surfaces of the conductive posts and the upper surface of the molding material in the method for fabricating the semiconductor package.

FIG. 10 is a cross-sectional view illustrating a step of forming a back side redistribution layer on the planarized upper surfaces of the conductive posts and the planarized upper surface of the molding material in the method for fabricating the semiconductor package.

FIG. 11 is a cross-sectional view illustrating a step of bonding a ring frame on the back side redistribution layer in the method for fabricating the semiconductor package.

FIG. 12 is a cross-sectional view illustrating a step of debonding the first carrier from the lower surface of the release layer in the method for fabricating the semiconductor package.

FIG. 13 is a cross-sectional view illustrating a step of removing the release layer from the lower surface of the front side redistribution layer in the method for fabricating the semiconductor package.

FIG. 14 is a cross-sectional view illustrating a step of forming external connection members on the lower surface of the front side redistribution layer, in the method for fabricating the semiconductor package.

FIG. 15 is a cross-sectional view illustrating a step of debonding the ring frame from the upper surface of the back side redistribution layer, in the method for fabricating the semiconductor package.

### DETAILED DESCRIPTION OF THE EMBODIMENTS

In the following detailed description, only certain embodiments of the present invention have been shown and described, simply by way of illustration. However, the present disclosure is not limited thereto since it can be variously implemented.

The drawings and description are to be regarded as illustrative in nature and not restrictive. Like reference numerals designate like elements throughout the specification.

Throughout this specification, when a part is referred to as being “connected” to another part, it may be directly connected to the other part, or may be connected to the other part indirectly with any other elements interposed therebetween.

Further, it will be understood that when an element such as a layer, film, region, or substrate is referred to as being “on” another element, it can be directly on the other element or intervening elements may also be present. Further, when an element is “above” or “on” a reference portion, the element is located above or below the reference portion, and it does not necessarily mean that the element is located “above” or “on” in a direction opposite to gravity.

Further, in the entire specification, when it is referred to as “on a plane”, it means when a target part is viewed from above, and when it is referred to as “on a cross-section”, it means when the cross-section obtained by cutting a target part vertically is viewed from the side.

Hereinafter, a semiconductor package and a method for fabricating the semiconductor package according to an embodiment will be described with reference to the drawings.

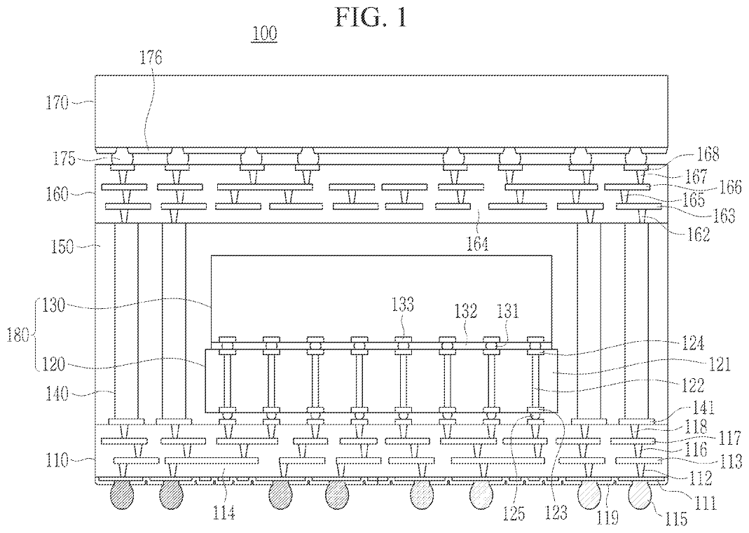

FIG. 1 is a cross-sectional view illustrating a semiconductor package 100 of an embodiment including a 3D IC structure 180 made by sequentially stacking a first semiconductor chip die 120 and a second semiconductor chip die 130 using connection members 131 in the process of fabricating the semiconductor package 100. For example, the second semiconductor chip die 130 may be stacked on top of the first semiconductor chip die 120.

Referring to FIG. 1, the semiconductor package 100 may include a front side redistribution layer 110, the 3D IC structure 180 including the first semiconductor chip die 120 and the second semiconductor chip die 130, conductive posts 140, a molding material 150, a back side redistribution layer 160, a third semiconductor chip die 170, and external connection members 115. The semiconductor package 100 may be used to implement a fan-out wafer-level package (FOWLP) or a fan-out panel-level package (FOPLP).

The front side redistribution layer 110 may include a dielectric layer 114, and first redistribution vias 112, first redistribution lines 113, second redistribution vias 116, second redistribution lines 117, and third redistribution via 118 formed in the dielectric layer 114. However, the disclosure is not limited thereto since the front side redistribution layer 110 may have fewer or more redistribution lines and redistribution vias in another embodiment of this disclosure.

The dielectric layer 114 may include or be a photosensitive polymer layer. Photosensitive polymers are materials applicable to a photolithography process to form fine patterns. In an embodiment, the dielectric layer 114 may include a photoimageable dielectric (PID) (a photosensitive dielectric) which is used in a redistribution process. In an embodiment, the photoimageable dielectric (PID) may include a polyimide-based photosensitive polymer, a novolac-based photosensitive polymer, polybenzoxazole, a silicon-based polymer, an acrylate-based polymer, or an epoxy-based polymer. In an embodiment, the photoimageable dielectric (PID) has a resolution of 3 μm.

The first redistribution vias 112 are disposed between the first redistribution lines 113 and bonding pads 111. The first redistribution vias 112 electrically couple the first redistribution lines 113 to the external connection members 115, which are connected to the bonding pads 111 in the vertical direction. The first redistribution lines 113 are disposed between the first redistribution vias 112 and the second redistribution vias 116. The first redistribution lines 113 electrically couple the first redistribution vias 112 with the second redistribution vias 116 in the horizontal direction. The second redistribution vias 116 are disposed between the first redistribution lines 113 and the second redistribution lines 117. The second redistribution vias 116 electrically couple the first redistribution lines 113 with the second redistribution lines 117 in the vertical direction. The second redistribution lines 117 are disposed between the second redistribution vias 116 and the third redistribution vias 118. The second redistribution lines 117 electrically couple the second redistribution vias 116 with the third redistribution vias 118 in the horizontal direction. The third redistribution vias 118 are disposed between the second redistribution lines 117 and bonding pads 141. The third redistribution vias 118 electrically couple the second redistribution lines 117 with the bonding pads 141 in the vertical direction.

The 3D IC structure 180 may include the first semiconductor chip die 120 and the second semiconductor chip die 130. A 3D IC is an integrated circuit implemented as a three-dimensional single chip by a technique of stacking circuits in the vertical direction, which differs from an existing technique of arranging circuits in the horizontal direction. If the vertical stacking technique is used, it is possible to implement more elements in a same silicon wafer area. Therefore, it becomes possible to reduce the manufacturing cost and increase the performance.

The first semiconductor chip die 120 may include first semiconductor chips 121, through-silicon vias (TSVs) 122, lower bonding pads 123, and upper bonding pads 124. In an embodiment, the first semiconductor chips 121 may include or be a central processing unit (CPU) or a graphic processing unit (GPU). The through-silicon vias (TSVs) 122 are disposed between the lower bonding pads 123 and the upper bonding pads 124. The through-silicon vias (TSVs) 122 electrically couple the lower bonding pads 123 with the upper bonding pads 124.

In the 3D IC structure 180, the second semiconductor chip die 130 is disposed apart from the front side redistribution layer 110 which transmits signals and power. For this reason, the through-silicon vias (TSVs) 122 are disposed between the first semiconductor chips 121 of the first semiconductor chip die 120 and are connected to the second semiconductor chip die 130 so as to increase the speed in receiving and responding signals and power of the second semiconductor chip die 130.

The lower bonding pads 123 are disposed between the through-silicon vias (TSVs) 122 and connection members 125, and electrically couple the through-silicon vias (TSVs) 122 with the connection members 125. The upper bonding pads 124 are disposed between the through-silicon vias (TSVs) 122 and the connection members 131. The upper bonding pads 124 electrically couple the through-silicon vias (TSVs) 122 to the second semiconductor chip die 130, which are connected to the connection members 131. The connection members 125 are disposed between the lower bonding pads 123 and the bonding pads 141 of the front side redistribution layer 110. The connection members 125 electrically couple the lower bonding pads 123 to the front side redistribution layer 110.

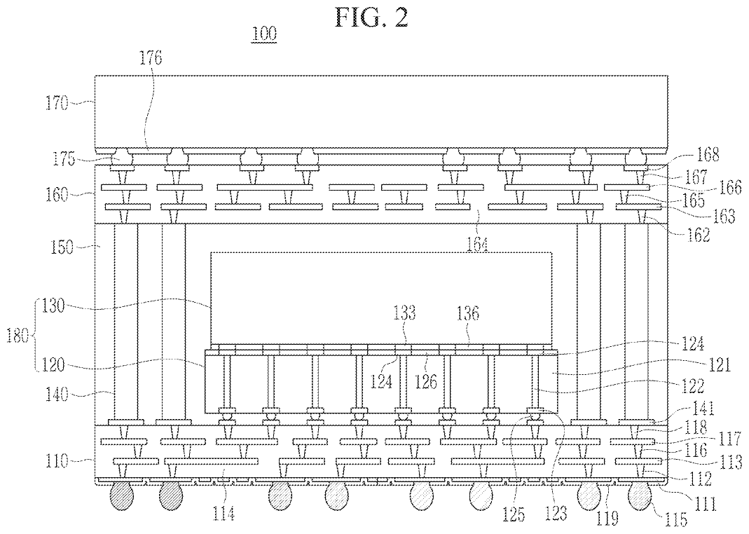

The second semiconductor chip die 130 may include additional semiconductor chips and additional bonding pads 133 other than those illustrated in FIG. 2. In an embodiment, the additional semiconductor chips may include or be a communication chip or sensor. The bonding pads 133 of the second semiconductor chip die 130 are bonded to the connection members 131 to be electrically coupled with the connection members 131. In an embodiment, the connection members 131 include or are micro bumps.

The connection members 131 may be surrounded between the first semiconductor chip die 120 and the second semiconductor chip die 130 by an insulating member 132. In an embodiment, the insulating member 132 extends over an entire lower surface of the second semiconductor chip die 130. The insulating member 132 may extend so as to protrude in a lateral direction from the space between the first semiconductor chip die 120 and the second semiconductor chip die 130. In an embodiment, side surfaces of the insulating member 132 are in direct contact with the molding material 150. In an embodiment, the insulating member 132 includes a molded underfill (MUF) material. In an embodiment, the insulating member 132 includes a non-conductive film (NCF).

The conductive posts 140 are disposed between the bonding pads 141 of the front side redistribution layer 110 and the fourth redistribution vias 162 of the back side redistribution layer 160. The conductive posts 140 electrically couple the bonding pads 141 of the front side redistribution layer 110 to the fourth redistribution vias 162 of the back side redistribution layer 160.

The molding material 150 encapsulates the first semiconductor chip die 120, the second semiconductor chip die 130, the connection members 125, the conductive posts 140, and the insulating member 132 on the front side redistribution layer 110. In an embodiment, the molding material 150 covers the side and lower surfaces of the first semiconductor chip die 120, the side and upper surfaces of the second semiconductor chip die 130, the side surfaces of the conductive posts 140, and the side surface of the insulating member 132, on the front side redistribution layer 110. For example, the molding material 150 may entirely surround first semiconductor chip die 120, the second semiconductor chip die 130, the connection members 125, the conductive posts 140, and the insulating member 132.

The back side redistribution layer 160 may include a dielectric layer 164, and the fourth redistribution vias 162, third redistribution lines 163, fifth redistribution vias 165, fourth redistribution lines 166, sixth redistribution vias 167, and bonding pads 168 formed in the dielectric layer 164. However, the back side redistribution layer 160 is not limited thereto since it may have fewer or more redistribution lines, redistribution vias, and bonding pads in an another embodiment of this disclosure.

The dielectric layer 164 may include or be a photosensitive polymer layer. Photosensitive polymers are materials applicable to a photolithography process to form fine patterns. In an embodiment, the dielectric layer 164 may include a photoimageable dielectric (PID) (a photosensitive dielectric), which is used in a redistribution process. In an embodiment, the photoimageable dielectric (PID) may include a polyimide-based photosensitive polymer, a novolac-based photosensitive polymer, polybenzoxazole, a silicon-based polymer, an acrylate-based polymer, or an epoxy-based polymer. In an embodiment, the photoimageable dielectric (PID) has a resolution of 3 μm.

The fourth redistribution vias 162 are disposed between the third redistribution lines 163 and the conductive posts 140. The fourth redistribution vias 162 electrically couple the third redistribution lines 163 to the conductive posts 140 in the vertical direction. The third redistribution lines 163 are disposed between the fourth redistribution vias 162 and the fifth redistribution vias 165. The third redistribution lines 163 electrically couple the fourth redistribution vias 162 to the fifth redistribution vias 165 in the horizontal direction. The fifth redistribution vias 165 are disposed between the third redistribution lines 163 and the fourth redistribution lines 166. The fifth redistribution vias 165 electrically couple the third redistribution lines 163 to the fourth redistribution lines 166 in the vertical direction. The fourth redistribution lines 166 are disposed between the fifth redistribution vias 165 and the sixth redistribution vias 167. The fourth redistribution lines 166 electrically couple the fifth redistribution vias 165 to the sixth redistribution vias 167 in the horizontal direction. The sixth redistribution vias 167 are disposed between the fourth redistribution lines 166 and the bonding pads 168. The sixth redistribution vias 167 electrically couple the fourth redistribution lines 166 to the bonding pads 168 in the vertical direction.

The bonding pads 168 are disposed between the sixth redistribution vias 167 and connection members 175. The bonding pads 168 electrically couple the sixth redistribution vias 167 with the connection members 175.

The external connection members 115 may electrically couple an external component (e.g., a circuit) to the front side redistribution layer 110 through the bonding pads 111 disposed beneath the front side redistribution layer 110. An insulating layer 119 may insulate the bonding pads 111 and the external connection members 115 from one another. The insulating layer 119 may have a plurality of openings for soldering. In an embodiment, the insulating layer 119 may include a solder resist material. The insulating layer 119 may prevent the external connection members 115 from being short-circuited.

The third semiconductor chip die 170 is disposed on the back side redistribution layer 160. The third semiconductor chip die 170 is electrically coupled to the back side redistribution layer 160 using the connection members 175. The third semiconductor chip die 170 may include an insulating layer 176 provided beneath it to prevent short-circuiting of the connection members 175. The insulating layer 176 may contact a bottom surface of the third semiconductor chip die 170. For example, the insulating layer 176 may insulate the connection members 175 from one another. In an embodiment, the insulating layer 176 may include a solder resist material.

FIG. 2 is a cross-sectional view illustrating a semiconductor package 100 of an embodiment including a 3D IC structure 180 made by sequentially stacking a first semiconductor chip die 120 and a second semiconductor chip die 130 by hybrid bonding in the process of fabricating the semiconductor package 100. For example, the second semiconductor chip die 130 may be stacked on top of the first semiconductor chip die 120.

Referring to FIG. 2, the semiconductor package 100 may include the 3D IC structure 180 made by bonding the first semiconductor chip die 120 to the second semiconductor chip die 130 by hybrid bonding. The first semiconductor chip die 120 may include bonding pads 124 and a silicon insulating layer 126 provided on its upper surface. For example, the silicon insulating layer 126 may contact an upper surface of the first semiconductor chip die 120. The second semiconductor chip die 130 may include bonding pads 133 and a silicon insulating layer 136 provided on its lower surface. For example, the silicon insulating layer 136 may contact the lower surface of the second semiconductor chip die 130. In an embodiment, the bonding pads 133 of the first semiconductor chip die 120 are directly bonded to the bonding pads 124 of the second semiconductor chip die 130 by metal-to-metal bonding of hybrid bonding, and the silicon insulating layer 126 of the first semiconductor chip die 120 is directly bonded to the silicon insulating layer 136 of the second semiconductor chip die 130 by nonmetal-to-nonmetal bonding of the hybrid bonding.

In an embodiment, the bonding pads 124 of the first semiconductor chip die 120 and the bonding pads 133 of the second semiconductor chip die 130 may include or be copper (Cu). In another embodiment, the bonding pads 124 of the first semiconductor chip die 120 and the bonding pads 133 of the second semiconductor chip die 130 may be a metallic material to which hybrid bonding can be applied. In an embodiment, the silicon insulating layer 126 of the first semiconductor chip die 120 and the silicon insulating layer 136 of the second semiconductor chip die 130 may include or be silicon oxide. In an embodiment, the silicon insulating layer 126 of the first semiconductor chip die 120 and the silicon insulating layer 136 of the second semiconductor chip die 130 may include or be SiO₂. In another embodiment, the silicon insulating layer 126 of the first semiconductor chip die 120 and the silicon insulating layer 136 of the second semiconductor chip die 130 may be silicon nitride, silicon oxynitride, or other suitable dielectric materials.

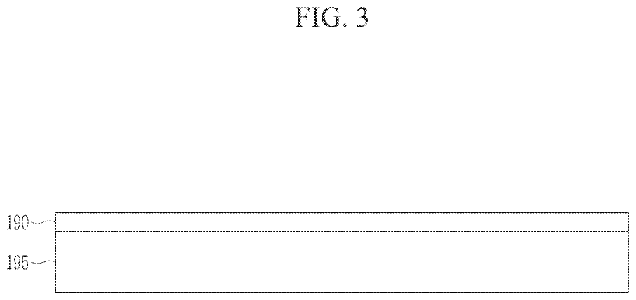

The features of the configuration of the semiconductor package 100 of FIG. 1 described above may be applied to the configuration of the semiconductor package 100 of FIG. 3 except that the first semiconductor chip die 120 and the second semiconductor chip die 130 are bonded by hybrid bonding.

FIG. 3 is a cross-sectional view illustrating a step of forming a first carrier 195 (e.g., a carrier layer) as one step of the method for fabricating the semiconductor package.

Referring to FIG. 3, the first carrier 195 is provided or formed. The first carrier 195 may include, for example, a silicon-based material such as glass or silicon oxide, an organic material, other materials such as aluminum oxide, an arbitrary combination thereof, or the like. On the first carrier 195, a release layer 190 is disposed. For example, the release layer 190 is formed or deposited on the first carrier 195. The release layer 190 may be composed of multiple layers, and may include, for example, an adhesive layer and a release layer. The release layer 190 may function to bond the front side redistribution layer 110 to the first carrier 195. The release layer 190 may be removed from the front side redistribution layer 110 together with the first carrier 195. In an embodiment, an upper surface of the release layer 190 is flattened to have a high coplanarity.

In an embodiment, the release layer 190 includes or is a polymer-based material. In an embodiment, the release layer 190 includes or is a light-to-heat-conversion (LTHC) release coating material, which may be thermally released by heating. In an embodiment, the release layer 190 includes or is an ultra-violet (UV) adhesive, which is peeled off by ultra-violet (UV) light. In another embodiment, the release layer 190 is peeled off by a physical method. In another embodiment, the release layer 190 is applied in a liquid and cured state.

In another embodiment, the release layer is a laminate film stacked on the first carrier 195.

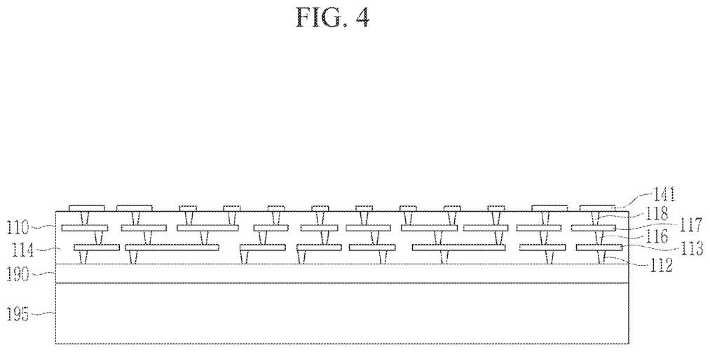

FIG. 4 is a cross-sectional view illustrating a step of forming a front side redistribution layer 110 on the release layer 190 provided on the first carrier 195, as one step of the method for fabricating the semiconductor package.

Referring to FIG. 4, the front side redistribution layer 110 is formed on the release layer 190 of the first carrier 195.

First, on the release layer 190, a dielectric layer 114 is formed. In an embodiment, the dielectric layer 114 is formed of a polymer such as Polyphenylene Benzobisoxale (PBO) or polyimide. In another embodiment, the dielectric layer 114 is formed of an inorganic dielectric material such as silicon nitride or silicon oxide. In an embodiment, the dielectric layer 114 may be formed by a chemical vapor deposition (CVD), an atomic layer deposition (ALD), or a plasma-enhanced chemical vapor deposition (PECVD) process.

After the dielectric layer 114 is formed, the first redistribution vias 112 are formed by selectively etching the dielectric layer 114 to form via holes and the via holes are filled with a conductive material.

Subsequently, an additional dielectric layer 114 is further deposited on the first redistribution vias 112 and the dielectric layer 114, and the first redistribution lines 113 are formed by selectively etching the additional deposited dielectric layer 114 to form openings and filling the openings with a conductive material.

Then, an additional dielectric layer 114 is further deposited on the first redistribution lines 113 and the dielectric layer 114, and the second redistribution vias 116 are formed by selectively etching the additional deposited dielectric layer 114 to form via holes and filling the via holest with a conductive material.

Subsequently, an additional dielectric layer 114 is further deposited on the second redistribution vias 116 and the dielectric layer 114, and the second redistribution lines 117 are formed by selectively etching the additional deposited dielectric layer 114 to form openings and filling the openings with a conductive material.

Next, an additional dielectric layer 114 is further deposited on the second redistribution lines 117 and the dielectric layer 114, and the third redistribution vias 118 are formed by selectively etching the additional deposited dielectric layer 114 to form via holes and filling the via holes with a conductive material.

In an embodiment, the first redistribution vias 112, the first redistribution lines 113, the second redistribution vias 116, the second redistribution lines 117, and the third redistribution vias 118 may include at least one of copper, aluminum, tungsten, nickel, gold, tin, titanium, and alloys thereof. In an embodiment, the first redistribution vias 112, the first redistribution lines 113, the second redistribution vias 116, the second redistribution lines 117, and the third redistribution vias 118 are formed by performing sputtering processes. In another embodiment, the first redistribution vias 112, the first redistribution lines 113, the second redistribution vias 116, the second redistribution lines 117, and the third redistribution vias 118 may be formed by forming a seed metal layer and then performing an electroplating process.

Then, the bonding pads 141 are formed on the dielectric layer 114 so as to be electrically coupled to the third redistribution vias 118 of the front side redistribution layer 110. The bonding pads 141 may include at least one of copper, aluminum, silver, tin, gold, nickel, lead, titanium, and alloys thereof.

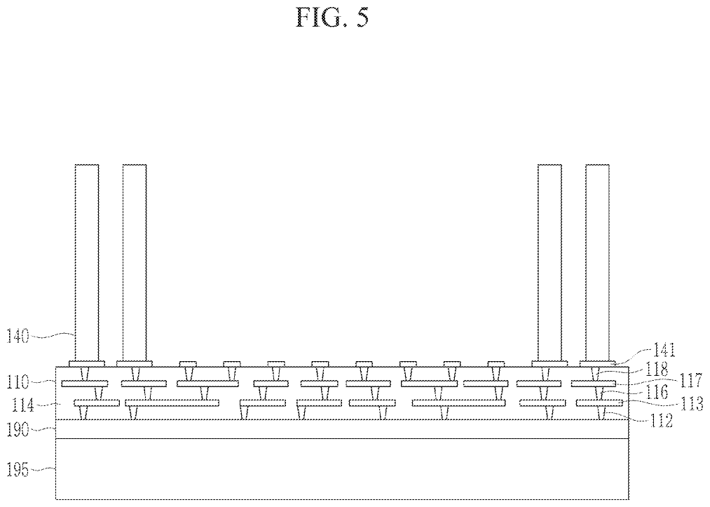

FIG. 5 is a cross-sectional view illustrating a step of forming the conductive posts 140 on the front side redistribution layer 110, as one step of the method for fabricating the semiconductor package.

Referring to FIG. 5, the conductive posts 140 are bonded to the bonding pads 141 of the front side redistribution layer 110 so as to extend in the vertical direction. In an embodiment, the conductive posts 140 are formed by performing a sputtering process. In another embodiment, the conductive posts 140 are formed by forming a metal seed layer and then performing an electroplating process. In an embodiment, the conductive posts 140 may be at least one of copper, nickel, gold, silver, aluminum, tungsten, titanium, tantalum, indium, molybdenum, manganese, cobalt, tin, magnesium, rhenium, beryllium, gallium, ruthenium, and alloys thereof.

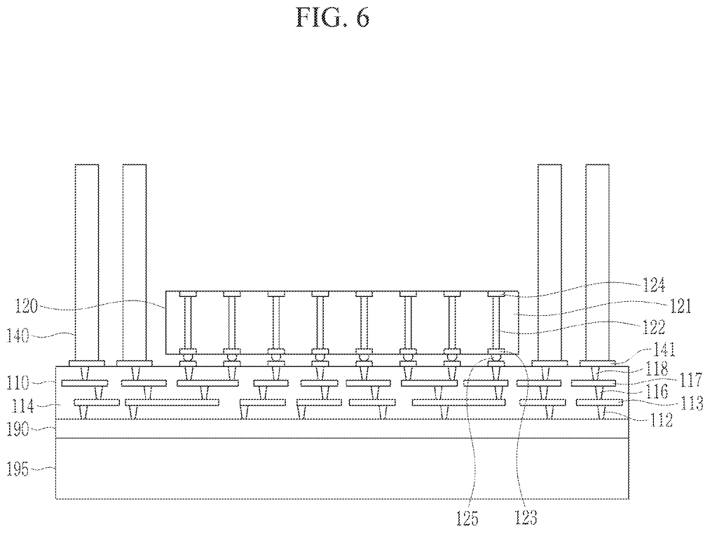

FIG. 6 is a cross-sectional view illustrating a step of bonding the first semiconductor chip die 120 to the front side redistribution layer 110, as one step of the method for fabricating the semiconductor package.

Referring to FIG. 6, the first semiconductor chip die 120 is bonded to the front side redistribution layer 110. In an embodiment, the bonding pads 141 of the front side redistribution layer 110 and the bonding pads 123 of the first semiconductor chip die 120 are bonded to the connection members 125 so as to be electrically coupled with each other. In the above process of fabricating the semiconductor package, a system-on-chip (SOC) may be formed as the 3D IC structure 180. Therefore, it is possible to reduce the manufacturing cost.

Since a system-on-chip (SOC) to be included in a package-on-package (POP) is fabricated in the process of fabricating the package-on-package (POP) as described above, a separate process for fabricating the system-on-chip (SOC) is unnecessary. Therefore, it is possible to reduce use of a molding material (EMC) which is may be used when a system-on-chip (SOC) is fabricated in a separate process.

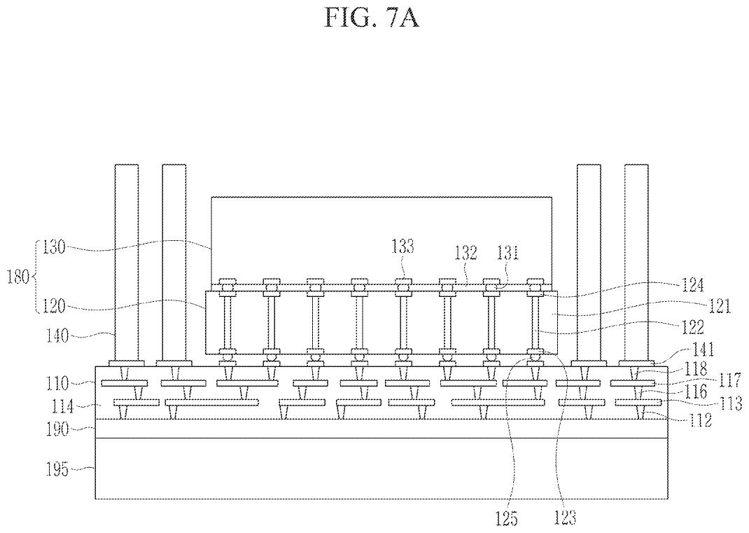

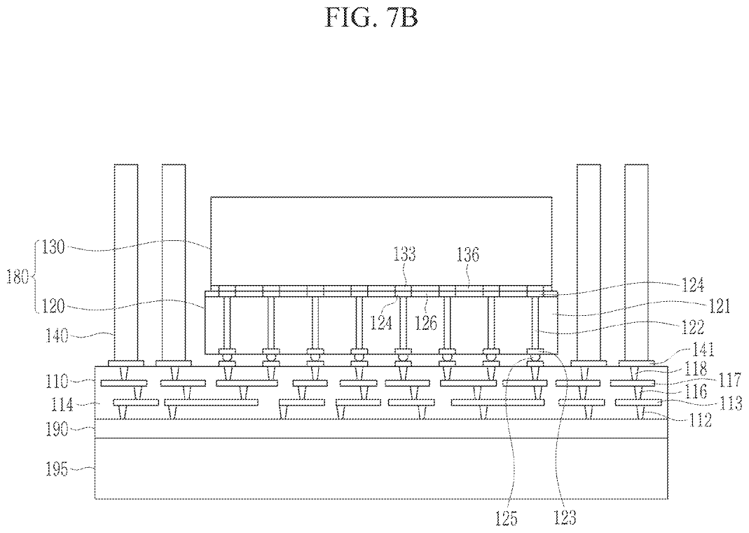

FIG. 7A is a cross-sectional view illustrating a step of bonding the second semiconductor chip die 130 to the first semiconductor chip die 120 using the connection members 131, following FIG. 6, as one step of the method for fabricating the semiconductor package.

Referring to FIG. 7A, the second semiconductor chip die 130 is bonded to the first semiconductor chip die 120. FIG. 7A illustrates the bonding being performed using the connection members 131 of FIG. 1. The bonding pads 133 of the second semiconductor chip die 130 and the bonding pads 124 of the first semiconductor chip die 120 may be bonded using the connection members 131. In an embodiment, the connection members 131 may include or be micro bumps.

In an embodiment, a non-conductive film (NCF) may be attached on the first semiconductor chip die 120 to form the insulating member 132. In an embodiment, the non-conductive film (NCF) has an adhesiveness property that enables it to be attached to the first semiconductor chip die 120. In an embodiment, the non-conductive film (NCF) has an uncured state that enables it to be deformed by an external force. The non-conductive film (NCF) may be attached to the first semiconductor chip die 120 by heating it to a temperature of ranging from about 170° C. to 300° C. for about 1 second to about 20 seconds. Subsequently, the second semiconductor chip die 130 is stacked on the non-conductive film (NCF). The connection members 131 provided on the second semiconductor chip die 130 may penetrate the non-conductive film (NCF) so as to come into contact with the first semiconductor chip die 120.

In another embodiment, after the second semiconductor chip die 130 is bonded to the first semiconductor chip die 120 using the connection members 131, the space between the first semiconductor chip die 120 and the second semiconductor chip die 130 may be filled with a molded underfill (MUF) material.

In this way, the insulating member 132 becomes disposed between the first semiconductor chip die 120 and the second semiconductor chip die 130. Therefore, it is possible to alleviate stress between the first semiconductor chip die 120 and the second semiconductor chip die 130.

Through this bonding step using the connection members 131, the second semiconductor chip die 130 is vertically stacked on the first semiconductor chip die 120. In this process of forming a package-on-package (POP), a system-on-chip (SOC) including the first semiconductor chip die 120 and the second semiconductor chip die 130 is formed as the 3D IC structure 180.

FIG. 7B is a cross-sectional view illustrating a step of bonding the second semiconductor chip die 130 to the first semiconductor chip die 120 using hybrid bonding, following FIG. 6, as one step of the method for fabricating the semiconductor package. FIG. 7B illustrates the bonding being performed using the bonding pads 136 of FIG. 2.

Referring to FIG. 7B, the second semiconductor chip die 130 is bonded to the first semiconductor chip die 120 using hybrid bonding. Hybrid bonding is bonding two devices by a method of fusing the same material of the two devices using the bonding property of the same material. Here, the hybrid bonding means performing two different types of bonding, for example, bonding two devices by a first type of metal-to-metal bonding and a second type of nonmetal-to-nonmetal bonding.

The bonding pads 124 of the first semiconductor chip die 120 and the bonding pads 133 of the second semiconductor chip die 130 may be directly bonded by metal-to-metal bonding of the hybrid bonding. By the metal-to-metal bonding of the hybrid bonding, metallic bonds are formed at the interfaces between the bonding pads 124 of the first semiconductor chip die 120 and the bonding pads 133 of the second semiconductor chip die 130. In an embodiment, the bonding pads 124 of the first semiconductor chip die 120 and the bonding pads 133 of the second semiconductor chip die 130 are the same material such that after hybrid bonding, the interfaces between the bonding pads 124 of the first semiconductor chip die 120 and the bonding pads 133 of the second semiconductor chip die 130 are removed. For example, a single unitary bonding pad comprising a bonding pad 124 and a corresponding bonding pad 133 may result from the hybrid bonding. Through the bonding pads 124 of the first semiconductor chip die 120 and the bonding pads 133 of the second semiconductor chip die 130, the first semiconductor chip die 120 and the second semiconductor chip die 130 can be electrically connected to each other.

The silicon insulating layer 126 of the first semiconductor chip die 120 may be directly bonded to the silicon insulating layer 136 of the second semiconductor chip die 130 by nonmetal-to-nonmetal bonding of the hybrid bonding. Using the nonmetal-to-nonmetal bonding of the hybrid bonding, a covalent bond is formed at the interface between the silicon insulating layer 126 of the first semiconductor chip die 120 and the silicon insulating layer 136 of the second semiconductor chip die 130. In an embodiment, the silicon insulating layer 126 of the first semiconductor chip die 120 and the silicon insulating layer 136 of the second semiconductor chip die 130 are a same material such that after hybrid bonding, the interface between the silicon insulating layer 126 of the first semiconductor chip die 120 and the silicon insulating layer 136 of the second semiconductor chip die 130 is removed. For example, a single unitary silicon insulating layer comprising the silicon insulating layer 126 and the silicon insulating layer 136 may result from the hybrid bonding.

If the first semiconductor chip die 120 and the second semiconductor chip die 130 are stacked by performing hybrid bonding, since separate solder balls are not necessarily required, it is possible to further miniaturize the semiconductor package. In this way, through this bonding step using hybrid bonding, the second semiconductor chip die 130 is vertically stacked on the first semiconductor chip die 120, and in the process of forming a package-on-package (POP), a system-on-chip (SOC) including the first semiconductor chip die 120 and the second semiconductor chip die 130 is formed as the 3D IC structure 180.

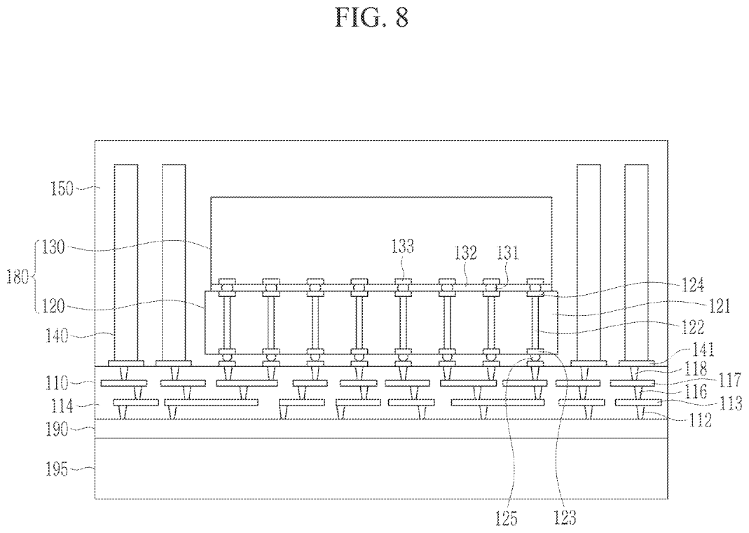

FIG. 8 is a cross-sectional view illustrating a step of encapsulating the 3D IC structure 180 and the conductive posts 140 within the molding material, as one step of the method for fabricating the semiconductor package.

Referring to FIG. 8, the 3D IC structure 180 and the conductive posts 140 are encapsulated on the front side redistribution layer 110 within the molding material 150. In some embodiments, the process of performing the encapsulating within the molding material 150 may include a compression molding or transfer molding process. In an embodiment, the molding material 150 is made of a thermosetting resin such as an epoxy resin. In another embodiment, the molding material 150 is an epoxy molding compound (EMC).

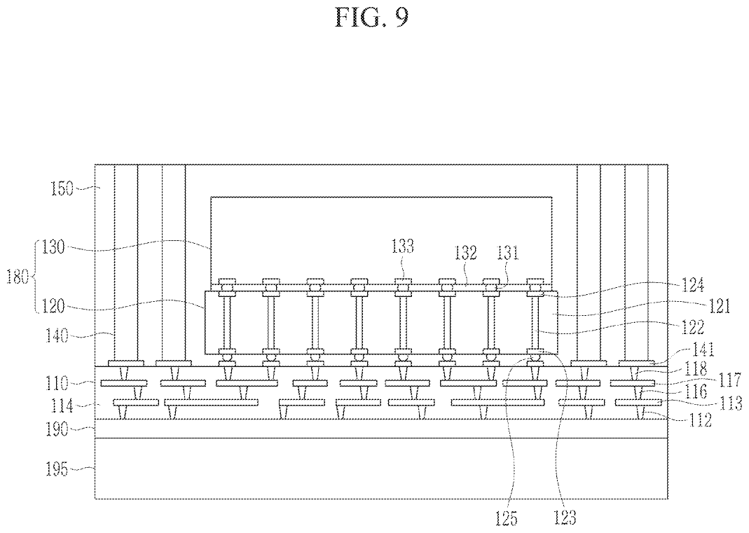

FIG. 9 is a cross-sectional view illustrating a step of planarizing upper surfaces of the conductive posts 140 and an upper surface of the molding material 150, as one step of the method for fabricating the semiconductor package.

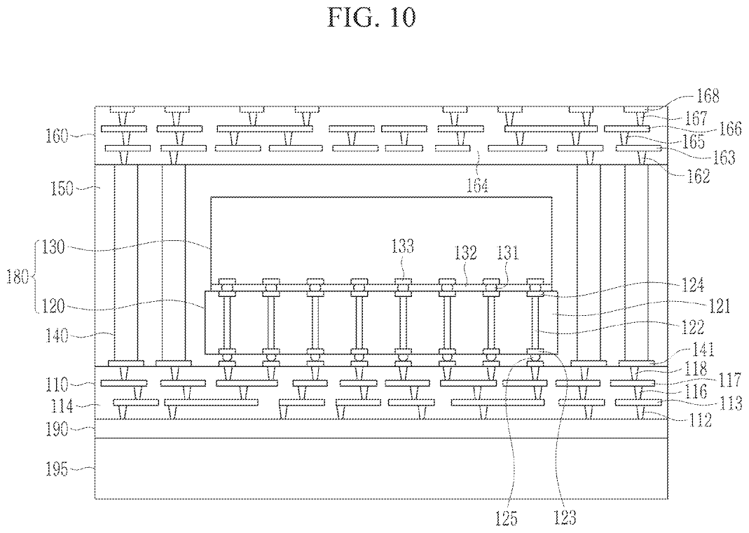

Referring to FIG. 10, chemical mechanical polishing (CMP) is performed to level the upper surfaces of the conductive posts 140 and the upper surface of the molding material 150. The CMP process or a mechanical grinding process may be applied to expose the upper surfaces of the conductive posts 140 and planarize the upper surfaces of the conductive posts 140 and the molding material 150. For example, the planarizing may remove portions of the conductive posts 140 and the molding material 150 and the remaining portions may be substantially level with one another.

FIG. 10 is a cross-sectional view illustrating a step of forming the back side redistribution layer 160 on the planarized upper surfaces of the conductive posts 140 and the planarized upper surface of the molding material 150, as one step of the method for fabricating the semiconductor package.

Referring to FIG. 10, the dielectric layer 164 is formed on the upper surfaces of the conductive posts 140 and the upper surface of the molding material 150. In an embodiment, the dielectric layer 164 is formed of a polymer such as PBO or polyimide. In another embodiment, the dielectric layer 164 is formed of an inorganic dielectric material such as silicon nitride or silicon oxide. In an embodiment, the dielectric layer 164 may be formed by a CVD, ALD, or PECVD process.

After the dielectric layer 164 is formed, the fourth redistribution vias 162 are formed by selectively etching the dielectric layer 164 to form via holes and filling the via holes with a conductive material. The fourth redistribution vias 162 are bonded to the conductive posts 140.

Subsequently, an additional dielectric layer 164 is further deposited on the fourth redistribution vias 162 and the dielectric layer 164, and the third redistribution lines 163 are formed by selectively etching the additional deposited dielectric layer 164 to form openings and filling the openings with a conductive material.

Then, an additional dielectric layer 164 is further deposited on the third redistribution lines 163 and the dielectric layer 164, and the fifth redistribution vias 165 are formed by selectively etching the additional deposited dielectric layer 164 to form via holes and filling the via holes with a conductive material.

Subsequently, an additional dielectric layer 164 is further deposited on the fifth redistribution vias 165 and the dielectric layer 164, and the fourth redistribution lines 166 are formed by selectively etching the additional deposited dielectric layer 164 to form openings and filling the openings with a conductive material.

Next, an additional dielectric layer 164 is further deposited on the fourth redistribution lines 166 and the dielectric layer 164, and the sixth redistribution vias 167 are formed by selectively etching the additional deposited dielectric layer 164 to form via holes and filling the via holes with a conductive material.

Subsequently, an additional dielectric layer 164 is further deposited on the sixth redistribution vias 167 and the dielectric layer 164, and the bonding pads 168 are formed by selectively etching the additional deposited dielectric layer 164 to form openings and filling the openings with a conductive material.

In an embodiment, the fourth redistribution vias 162, the third redistribution lines 163, the fifth redistribution vias 165, the fourth redistribution lines 166, the sixth redistribution vias 167, and the bonding pads 168 may include at least one of copper, aluminum, tungsten, nickel, gold, tin, titanium, and alloys thereof. In an embodiment, the fourth redistribution vias 162, the third redistribution lines 163, the fifth redistribution vias 165, the fourth redistribution lines 166, the sixth redistribution vias 167, and the bonding pads 168 may be formed by performing sputtering processes. In another embodiment, the fourth redistribution vias 162, the third redistribution lines 163, the fifth redistribution vias 165, the fourth redistribution lines 166, the sixth redistribution vias 167, and the bonding pads 168 are formed by forming a seed metal layer and performing an electroplating process.

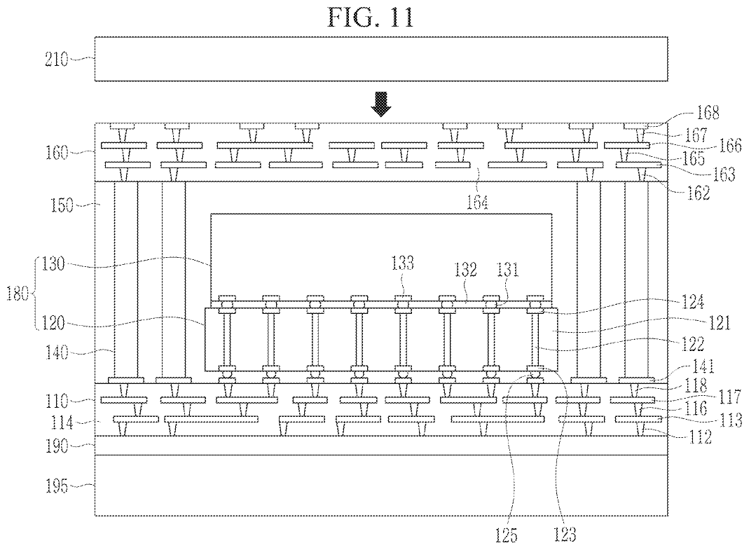

FIG. 11 is a cross-sectional view illustrating a step of bonding a ring frame 210 to the back side redistribution layer 160, as one step of the method for fabricating the semiconductor package.

Referring to FIG. 11, the ring frame 210 is attached to the back side redistribution layer 160. In an embodiment, the ring frame 210 is attached to the back side redistribution layer 160 by an adhesive sheet.

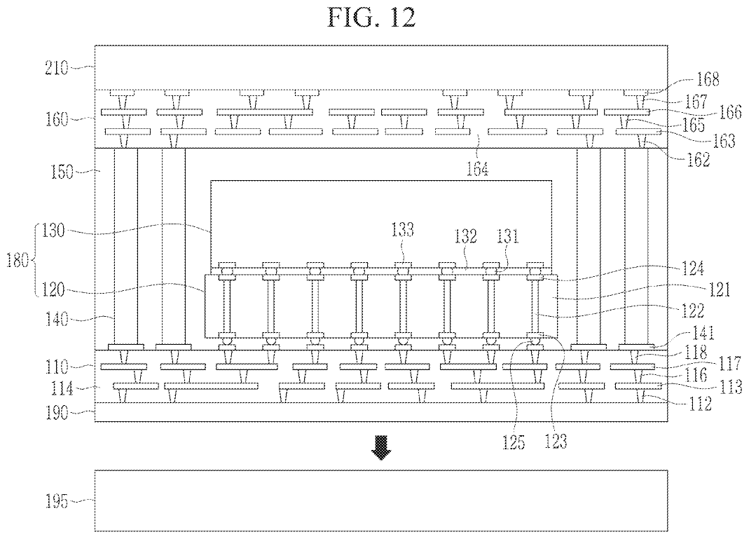

FIG. 12 is a cross-sectional view illustrating a step of debonding the first carrier 195 from the lower surface of the release layer 190, as one step of the method for fabricating the semiconductor package.

Referring to FIG. 12, the first carrier 195 is debonded from the lower surface of the release layer 190. For example, the first carrier 195 may be removed or separated from its bonding with the release layer 190.

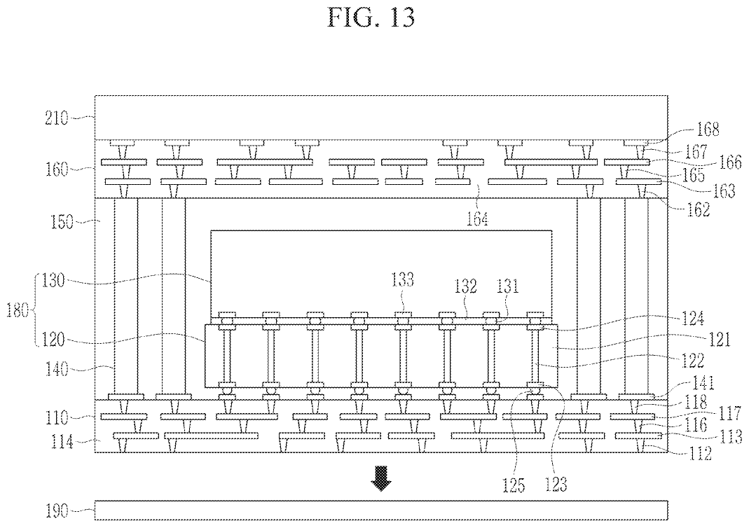

FIG. 13 is a cross-sectional view illustrating a step of debonding the release layer 190 from the lower surface of the front side redistribution layer 110, as one step of the method for fabricating the semiconductor package. For example, the release layer 190 may be removed or separated from its bonding with the front side redistribution layer 110.

Referring to FIG. 13, the first carrier 195 is debonded from the lower surface of the front side redistribution layer 110. In another embodiment, the first carrier 195 may be removed together with the release layer when the release layer 190 is removed. For example, a single step may be performed to simultaneously remove both the first carrier 195 and the release layer 190.

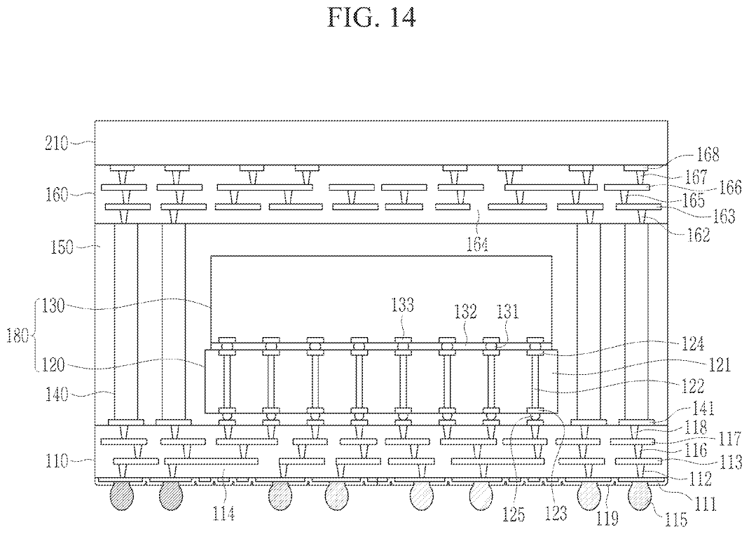

FIG. 14 is a cross-sectional view illustrating a step of forming the external connection members 115 on the lower surface of the front side redistribution layer 110, as one step of the method for fabricating the semiconductor package.

Referring to FIG. 14, the insulating layer 119 may be formed on a lower surface of the dielectric layer 114 of the front side redistribution layer 110, and the bonding pads 111 may be formed on the first redistribution vias 112, and the external connection members 115 may be formed on lower surfaces of the bonding pads 111. In an embodiment, the insulating layer 119 may be solder resist. The insulating layer 119 may have a plurality of openings for soldering of the external connection members 115 and the bonding pads 111. For example, portions of the insulating layer 119 may be removed to form the openings. In an embodiment, the bonding pads 111 may include at least one of copper, nickel, zinc, gold, silver, platinum, palladium, chromium, titanium, and alloys thereof. In an embodiment, the external connection members 115 may include at least one of tin, silver, lead, nickel, copper, or alloys thereof.

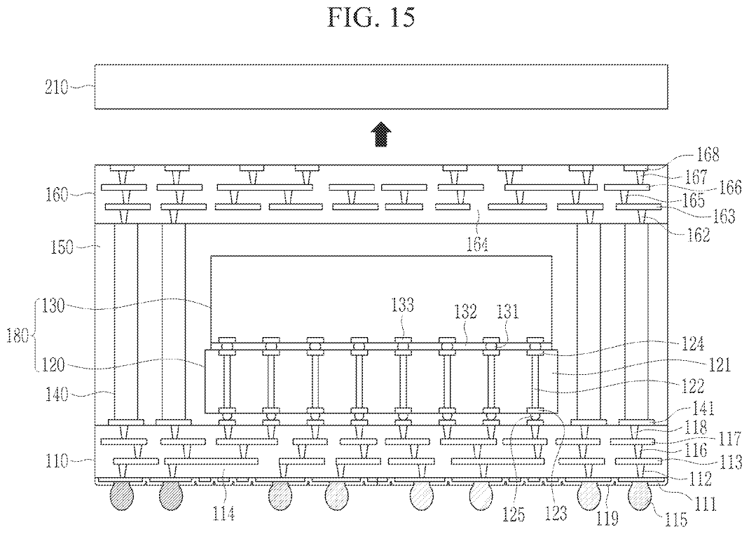

FIG. 15 is a cross-sectional view illustrating a step of debonding the ring frame 210 from the upper surface of the back side redistribution layer 160, as one step of the method for fabricating the semiconductor package.

Referring to FIG. 15, the ring frame 210 is debonded from the upper surface of the back side redistribution layer 160. For example, the ring frame 210 may removed or separate from its bonding with the back side redistribution layer 160.

While this disclosure has been described in connection with what is presently considered to be practical embodiments, it is to be understood that the disclosure is not limited to the disclosed embodiments. On the contrary, it is intended to cover various modifications and equivalent arrangements included within the spirit and scope of the appended claims.

What is claimed is:

1. A semiconductor package comprising:
a front side redistribution layer;
a three-dimensional integrated circuit (3D IC) structure disposed on the front side redistribution layer, the 3D IC structure including a first semiconductor chip die having through-silicon vias (TSVs) and a second semiconductor chip die disposed on the first semiconductor chip die, wherein the second semiconductor chip die is electrically coupled to the front side redistribution layer by the TSVs;
a plurality of connection members disposed between the first semiconductor chip die and the second semiconductor chip die;
an insulating member disposed between the first semiconductor chip die and the second semiconductor chip die to surround the plurality of connection members;
a molding material disposed on the front side redistribution layer to encapsulate the first semiconductor chip die, the second semiconductor chip die, and the insulating member; and
a back side redistribution layer disposed on the molding material.

2. The semiconductor package of claim 1, wherein:
each connection member of the plurality of connection members includes a micro bump.

3. The semiconductor package of claim 1, wherein:
the insulating member includes a molded underfill (MUF) material.

4. The semiconductor package of claim 1, wherein:
the insulating member includes a non-conductive film (NCF).

5. The semiconductor package of claim 1, wherein:
each connection member of the plurality of connection members includes a first bonding pad bonded to the first semiconductor chip die, and a second bonding pad bonded to the second semiconductor chip die.

6. The semiconductor package of claim 5, wherein:
the first bonding pad is directly bonded to the second bonding pad.

7. The semiconductor package of claim 5, wherein:
the first bonding pad and the second bonding pad include copper (Cu).

8. The semiconductor package of claim 1, wherein:
the insulating member includes a first insulating layer bonded to the first semiconductor chip die, and a second insulating layer bonded to the second semiconductor chip die.

9. The semiconductor package of claim 8, wherein:
the first insulating layer is directly bonded to the second insulating layer.

10. The semiconductor package of claim 8, wherein:
the first insulating layer and the second insulating layer include silicon oxide.

11. A semiconductor package comprising:
a front side redistribution layer;
a three-dimensional integrated circuit (3D IC) structure disposed on the front side redistribution layer, the 3D IC structure including a first semiconductor chip die having through-silicon vias (TSVs) and a second semiconductor chip die disposed on the first semiconductor chip die, wherein the second semiconductor chip die is electrically coupled to the front side redistribution layer by the through-silicon vias (TSVs);
a plurality of first connection members disposed between the first semiconductor chip die and the second semiconductor chip die to electrically couple the first semiconductor chip die to the second semiconductor chip die;
a plurality of second connection members disposed between the first semiconductor chip die and the front side redistribution layer to electrically couple the first semiconductor chip die to the front side redistribution layer;
an insulating member disposed between the first semiconductor chip die and the second semiconductor chip die to surround the plurality of first connection members;
a plurality of conductive posts bonded to the front side redistribution layer and disposed side by side next to the 3D IC structure on the front side redistribution layer;
a molding material disposed on the front side redistribution layer to encapsulate the first semiconductor chip die, the second semiconductor chip die, the insulating member, the plurality of second connection members, and the plurality of conductive posts;
a back side redistribution layer disposed on the molding material and the plurality of conductive posts and bonded to the plurality of conductive posts; and
a third semiconductor chip die disposed on the back side redistribution layer.

12. The semiconductor package of claim 11, wherein:
the first semiconductor chip die includes a central processing unit (CPU) or a graphic processing unit (GPU).

13. The semiconductor package of claim 11, wherein:
the second semiconductor chip die includes a communication chip or a sensor.

14. The semiconductor package of claim 11, wherein:
the third semiconductor chip die includes a semiconductor memory.

15. The semiconductor package of claim 11, wherein:
the 3D IC structure includes a system-on-chip (SOC).

16. The semiconductor package of claim 11, wherein:
the molding material includes an epoxy molding compound (EMC).

17. A method for fabricating a semiconductor package, comprising:
forming a front side redistribution layer on a carrier;
forming a three-dimensional integrated circuit (3D IC) structure on the front side redistribution layer,
wherein the forming of the 3D IC structure comprises:
mounting a first semiconductor chip die to the front side redistribution layer; and
bonding a second semiconductor chip die to the first semiconductor chip die using a plurality of connection members, wherein the plurality of connection members are surrounded by an insulating member;
encapsulating the first semiconductor chip die, the second semiconductor chip die, and the insulating member on the front side redistribution layer within a molding material; and
forming a back side redistribution layer on the molding material.

18. The method for fabricating the semiconductor package according to claim 17, wherein the bonding of the second semiconductor chip die to the first semiconductor chip die using the plurality of connection members is performed by hybrid bonding.

19. The method for fabricating the semiconductor package according to claim 17, wherein the bonding of the second semiconductor chip die to the first semiconductor chip die using the plurality of connection members comprises:
attaching a non-conductive film (NCF) to the first semiconductor chip die; and
attaching the second semiconductor chip die to the non-conductive film (NCF).

20. The method for fabricating the semiconductor package according to claim 17, further comprising:
filling a molded underfill (MUF) material between the first semiconductor chip die and the second semiconductor chip die, after the bonding of the second semiconductor chip die to the first semiconductor chip die using the plurality of connection members.
